(19) United States
(12) Patent Application Publication
(10) Pub. No.: US 2024/0087946 A1
(43) Pub. Date: Mar. 14, 2024

(54) SUBSTRATE PROCESSING APPARATUS, METHOD OF CLEANING, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Yoshitomo HASHIMOTO, Toyama (JP); Naofumi OHASHI, Toyama (JP)

(73) Assignee: KOKUSAI ELECTRIC CORPORATION, Tokyo (JP)

(21) Appl. No.: 18/368,096

(22) Filed: Sep. 14, 2023

(30) Foreign Application Priority Data
Sep. 14, 2022 (JP) 2022-146414

(51) Int. Cl. H01L 21/687; H01L 21/67

(52) U.S. Cl. CPC H01L 21/68764; H01L 21/6719; H01L 21/67248; H01L 21/67253

(57) ABSTRACT

There is provided a technique that includes: a substrate mounting table vertically movable and incorporating a heating mechanism; a process chamber divided by the substrate mounting table into a process region where a substrate is processed and a transfer region where transfer of the substrate is performed; a cooling gas supply system that supplies a cooling gas into the process chamber; a cleaning gas supply system that supplies a cleaning gas into the process chamber; an exhaust system that exhausts the process chamber; a controller capable of controlling the substrate mounting table, the cooling gas supply system, the cleaning gas supply system, and the exhaust system to perform: supplying the cooling gas into the process chamber in a state where the substrate mounting table is moved below the process region; and supplying the cleaning gas into the process chamber at a temperature lower than a temperature during substrate processing.

### CROSS-REFERENCE TO RELATED APPLICATION

This application is based upon and claims the benefit of priority from Japanese Patent Application No. 2022-146414, filed on Sep. 14, 2022, the entire contents of which are incorporated herein by reference.

### FIELD

The present disclosure relates to a substrate processing apparatus, a method of cleaning, a method of manufacturing a semiconductor device, and a recording medium.

### DESCRIPTION OF THE RELATED ART

As one of the processes of manufacturing a semiconductor device, a process of gas-purging the inside of a reaction furnace may be performed after performing film forming processing and unloading the processed substrate and in a state where there is no substrate in the reaction furnace (for example, see JP 2011-66106 A and WO 2005/050725 A).

### SUMMARY

In some cases, cleaning processing is performed in order to remove deposits that adhere to the process chamber, which is inside the reaction furnace. However, a defect may occur in a portion when cleaning processing is performed at a high temperature after substrate processing is performed at a high temperature. Therefore, after the substrate processing and before performing the cleaning processing, the temperature inside the process chamber may be lowered to a desired temperature.

The present disclosure provides a technique capable of efficiently cooling the process chamber.

According to some embodiments of the present disclosure, there is provided a technique that includes:
a substrate mounting table that is vertically movable and in which a heating mechanism is incorporated;
a process chamber divided, by movement of the substrate mounting table, into a process region where a substrate is processed and a transfer region that is disposed below the process region and where transfer of the substrate is performed;
a cooling gas supply system that supplies a cooling gas into the process chamber;
a cleaning gas supply system that supplies a cleaning gas into the process chamber;
an exhaust system that exhausts the process chamber; and
a controller configured to be capable of controlling the substrate mounting table, the cooling gas supply system, the cleaning gas supply system, and the exhaust system so as to perform: supplying the cooling gas into the process chamber in a state where the substrate mounting table is moved below the process region; and supplying the cleaning gas into the process chamber at a temperature lower than a temperature during substrate processing in which the substrate is processed.

### BRIEF DESCRIPTION OF THE DRAWINGS

FIG. 1 is a longitudinal sectional view for describing a configuration of a substrate processing apparatus according to some embodiments of the present disclosure, and is a diagram illustrating a mode of a process chamber during a substrate processing process.

FIG. 2 is a longitudinal sectional view for describing the configuration of the substrate processing apparatus according to some embodiments of the present disclosure, and is a diagram illustrating a mode of the process chamber during a substrate loading/unloading process.

FIG. 3 is a longitudinal sectional view for describing the configuration of the substrate processing apparatus according to some embodiments of the present disclosure, and is a diagram illustrating a mode of the process chamber during a cooling process.

FIG. 4 is a block diagram for describing a configuration of a controller of the substrate processing apparatus according to some embodiments of the present disclosure.

FIG. 5 is an example of a flowchart for describing the substrate processing process according to some embodiments of the present disclosure.

FIG. 6 is a longitudinal sectional view for describing a configuration of a substrate processing apparatus according to other embodiments of the present disclosure, and is a diagram illustrating a mode of a process chamber during a cooling process.

### DETAILED DESCRIPTION

### Embodiments of the Present Disclosure

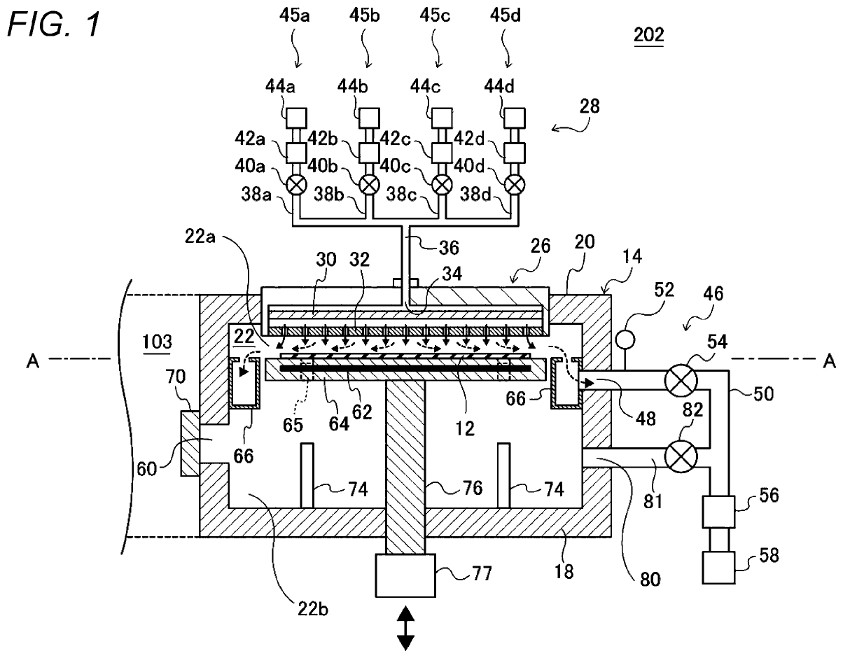

Some embodiments of the present disclosure will be described below mainly with reference to FIGS. 1 to 5. Furthermore, the drawings used in the following description are all schematic, and thus, dimensional relationships between constituent elements, ratios between constituent elements, and the like illustrated in the drawings do not necessarily coincide with realities. In addition, a plurality of drawings do not necessarily coincide with one another in dimensional relationships between constituent elements, ratios between constituent elements, and the like.

(1) Configuration of Substrate Processing Apparatus

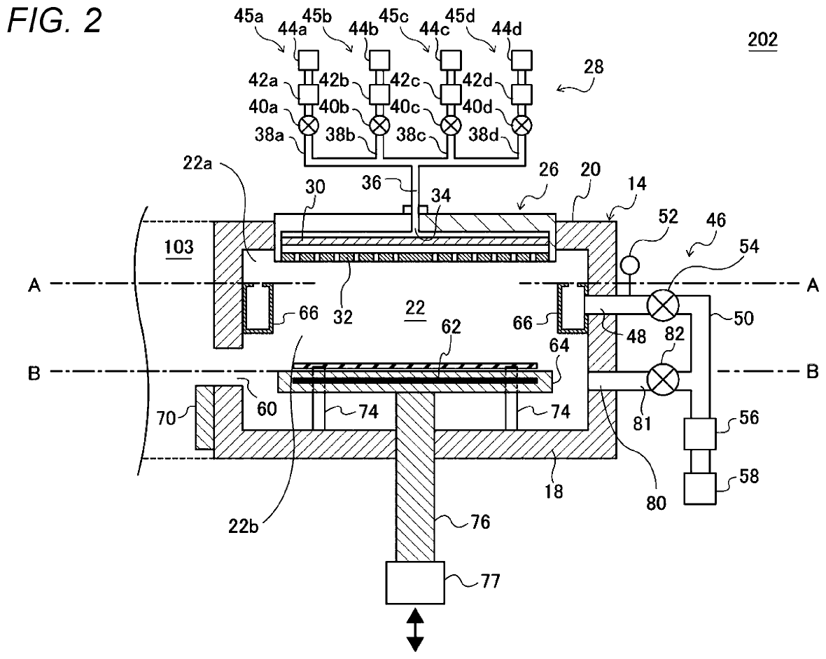

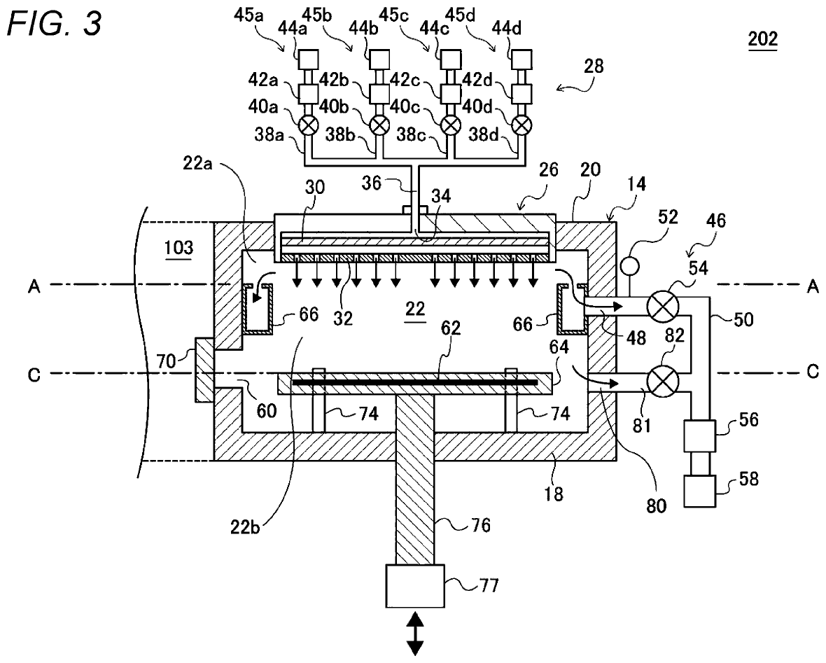

FIG. 1 is a diagram illustrating a state of a process container 202 of a substrate processing apparatus during a substrate processing process in which a substrate 12 is processed, where a susceptor 64 serving as a substrate mounting table is elevated and is at a substrate processing position A. FIG. 2 is a diagram illustrating a state of the process container 202 of the substrate processing apparatus during a substrate loading/unloading process in which the substrate 12 is loaded and unloaded, where the susceptor 64 is lowered and is at a substrate transfer position B. FIG. 3 is a diagram illustrating a state of the process container 202 of the substrate processing apparatus during a cooling process in which the inside of the process container 202 is cooled, where the susceptor 64 is lowered and is at a cooling position C.

(Process Container)

The process container 202 includes a container 14 in which the substrate 12 is processed. The container 14 communicates with a substrate transfer chamber 103 through a gate valve 70.

The container 14 includes a container body 18, an upper portion of which is opened, and a lid 20 that closes the upper opening of the container body 18. A process chamber 22 with a sealed structure is formed inside the container 14. As illustrated in FIG. 1, in a state where a substrate mounting surface of the susceptor 64 is at the substrate processing position A, an upper side (that is, a space above the substrate mounting surface of the susceptor 64) in the process chamber 22 forms a process region 22a where a substrate is processed, and a lower side (that is, a space below the substrate mounting surface of the susceptor 64) in the process chamber 22 forms a transfer region 22b where transfer of the substrate is performed. That is, the process chamber 22 includes the process region 22a, which is partitioned by the susceptor 64 in a state where the susceptor 64 is moved and is positioned at the substrate processing position A, and the transfer region 22b disposed below the process region 22a.

(Gas Introducer)

The lid 20 is provided with a gas introducer 26 and a gas supply system 28. The gas introducer 26 is provided in the lid 20, is disposed so as to face the substrate 12 in the process chamber 22, and is provided for supplying a process gas into the process chamber 22. The gas introducer 26 includes a gas distributor 30 that is provided on a gas introduction upstream side and has a plurality of gas holes, and a shower plate 32 that is provided on a gas introduction downstream side of the gas distributor 30 and has a large number of gas holes. The shower plate 32 distributes a gas in a shower-like manner.

(Gas Supply System)

The gas supply system 28 is connected to a gas introduction port 34 formed substantially at the center of the upper surface of the gas introducer 26, and is configured to supply a process gas into the process chamber 22 through the gas introducer 26. The gas supply system 28 includes a gas supply pipe 36 communicating with the gas introduction port 34 and gas supply pipes 38a, 38b, 38c, and 38d branched from the gas supply pipe 36 on a gas supply upstream side of the gas supply pipe 36. Further, the gas supply system 28 includes valves 40a, 40b, 40c, and 40d as opening/closing valves that open and close the respective gas flow paths and mass flow controllers (MFCs) 42a, 42b, 42c, and 42d as gas flow rate controllers, which are respectively provided in the gas supply pipes 38a, 38b, 38c, and 38d. The gas supply system 28 supplies desired types of gases into the process chamber 22 at a desired gas flow rate and a desired gas ratio.

The gas supply pipe 38a is provided with a gas supply source 44a, the MFC 42a, and the valve 40a in this order from a gas supply upstream direction. The gas supply pipe 38b is provided with a gas supply source 44b, the MFC 42b, and the valve 40b in this order from the gas supply upstream direction. The gas supply pipe 38c is provided with a gas supply source 44c, the MFC 42c, and the valve 40c in this order from the gas supply upstream direction. The gas supply pipe 38d is provided with a gas supply source 44d, the MFC 42d, and the valve 40d in this order from the gas supply upstream direction.

A source gas as a process gas is supplied from the gas supply pipe 38a into the process chamber 22 through the MFC 42a, the valve 40a, the gas supply pipe 36, the gas introduction port 34, and the gas introducer 26. In addition, a reactant gas as a process gas that reacts with the source gas is supplied from the gas supply pipe 38b into the process chamber 22 through the MFC 42b, the valve 40b, the gas supply pipe 36, the gas introduction port 34, and the gas introducer 26. An inert gas is supplied from the gas supply pipe 38c into the process chamber 22 through the MFC 42c, the valve 40c, the gas supply pipe 36, the gas introduction port 34, and the gas introducer 26. A cleaning gas that cleans the inside of the process chamber 22 is supplied from the gas supply pipe 38d into the process chamber 22 through the MFC 42d, the valve 40d, the gas supply pipe 36, the gas introduction port 34, and the gas introducer 26. Furthermore, the inert gas supplied from the gas supply pipe 38c is used also as a cooling gas that cools the inside of the process chamber 22.

A source gas supply system 45a includes the gas supply pipe 38a, the MFC 42a, the valve 40a, the gas supply pipe 36, the gas introduction port 34, and the gas introducer 26. The gas supply source 44a may be included in the source gas supply system 45a. A reactant gas supply system 45b includes the gas supply pipe 38b, the MFC 42b, the valve 40b, the gas supply pipe 36, the gas introduction port 34, and the gas introducer 26. The gas supply source 44b may be included in the reactant gas supply system 45b. The source gas supply system 45a and the reactant gas supply system 45b may be referred to as a process gas supply system.

An inert gas supply system 45c includes the gas supply pipe 38c, the MFC 42c, the valve 40c, the gas supply pipe 36, the gas introduction port 34, and the gas introducer 26. The gas supply source 44c may be included in the inert gas supply system 45c. The inert gas supply system 45c may be referred to as a cooling gas supply system or a purge gas supply system.

A cleaning gas supply system 45d includes the gas supply pipe 38d, the MFC 42d, the valve 40d, the gas supply pipe 36, the gas introduction port 34, and the gas introducer 26. The gas supply source 44d may be included in the cleaning gas supply system 45d.

(Periphery of Susceptor)

Exhaust holes 48 and 80, a transfer port 60, and the susceptor 64 are provided in the container body 18. The exhaust hole 48 is provided in one side of the container body 18. An annular passage 66 that communicates with the process region 22a is provided on an upper inner periphery of the container body 18. The annular passage 66 is formed to communicate with the exhaust hole 48. That is, the exhaust hole 48 is provided so as to communicate with the process region 22a through the annular passage 66. The container body 18 is configured such that the atmosphere inside the process region 22a is exhausted through the annular passage 66 and the exhaust hole 48.

The exhaust hole 80 is provided below the exhaust hole 48 in the one side of the container body 18. The exhaust hole 80 is provided so as to communicate with the transfer region 22b. The container body 18 is configured such that the atmosphere inside the transfer region 22b is exhausted through the exhaust hole 80.

The transfer port 60 is provided in another side of the container body 18. The another side faces the exhaust holes 48 and 80. The transfer port 60 of the container body 18 is provided with the gate valve 70 serving as an opening/closing valve that isolates the atmosphere in the substrate transfer chamber 103 from that in the process chamber 22, in an openable and closable manner. An unprocessed substrate 12 is loaded from the substrate transfer chamber 103 into the process chamber 22 through the transfer port 60, and a processed substrate 12 is unloaded from the process chamber 22 to the substrate transfer chamber 103 through the transfer port 60.

(Susceptor)

In the process chamber 22 of the container 14, the susceptor 64 is provided so as to be capable of vertical movement (or vertically movable). The susceptor 64 incorporates a heater 62 serving as a heating mechanism, and the substrate 12 is mounted on the substrate mounting surface of the susceptor 64. The susceptor 64 is configured to heat the substrate 12 by the heater 62 through the susceptor 64.

A plurality of support pins 74 are erected on an inner bottom of the container body 18. These support pins 74 are formed to be able to pass through the heater 62 and the susceptor 64, and to be able to protrude or not from the surface of the susceptor 64 in response to the lowering or elevating of the susceptor 64.

When the susceptor 64 is lowered and is at a position where the substrate loading/unloading process can be performed (see FIG. 2, hereinafter, the position being referred to as the substrate transfer position B), the plurality of support pins 74 protrude from the susceptor 64 to allow the substrate 12 to be supported on the plurality of support pins 74. In addition, the substrate 12 can be loaded or unloaded between the process chamber 22 and the substrate transfer chamber 103 through the transfer port 60. In contrast, when the susceptor 64 is elevated and is at a position that is above the substrate transfer position B and where the substrate processing process such as a film forming process can be performed (see FIG. 1, hereinafter, the position being referred to as the substrate processing position A), the substrate 12 is mounted on the susceptor 64 without involvement of the support pins 74.

The susceptor 64 is supported by a support shaft 76. The support shaft 76 is coupled to an elevation rotator 77. The susceptor 64 is configured to be vertically movable inside the process chamber 22 by being elevated or lowered by the elevation rotator 77. The elevation rotator 77 is configured to be capable of adjusting the vertical position of the susceptor 64 inside the process chamber 22 in multiple stages (the substrate processing position A, the substrate transfer position B, the cooling position C, and the like), in each process such as the substrate loading process, the film forming process, the substrate unloading process, the cooling process, and a cleaning process.

In addition, the susceptor 64 is configured to be rotated about the support shaft 76 by the rotation of the support shaft 76 by the elevation rotator 77. That is, the susceptor 64 is configured to be rotatable at an arbitrary rate while holding the substrate 12.

(Exhaust System)

The container body 18 is provided with an exhaust system 46 that exhausts the atmosphere inside the process chamber 22 through the exhaust holes 48 and 80. An exhaust pipe 50 is connected to the exhaust hole 48. An exhaust pipe 81 is connected to the exhaust hole 80. The exhaust pipe 50 is provided with a pressure sensor 52, a valve 54, an APC valve 56 as a pressure regulator that regulates the pressure inside the process chamber 22, and a vacuum pump 58 in this order from the gas flow upstream direction. The exhaust pipe 81 is provided with a valve 82. The exhaust pipe 81 is connected to the exhaust pipe 50 between the valve 54 and the APC valve 56. The exhaust system 46 includes the exhaust pipe 50, the pressure sensor 52, the valve 54, the exhaust pipe 81, the valve 82, and the APC valve 56. The vacuum pump 58 may be included in the exhaust system 46. The pressure sensor 52 monitors the pressure inside the process chamber 22. The MFCs 42a to 42d, the valves 40a to 40d, 54, and 82, the APC valve 56, and the like are controlled on the basis of a pressure value acquired by the pressure sensor 52 to regulate a gas supply amount and a gas exhaust amount. As a result, the pressure inside the process chamber 22 is controlled to a desired value.

(Controller)

A controller 121 serving as a control means controls constituents described above so as to perform the substrate processing process described later.

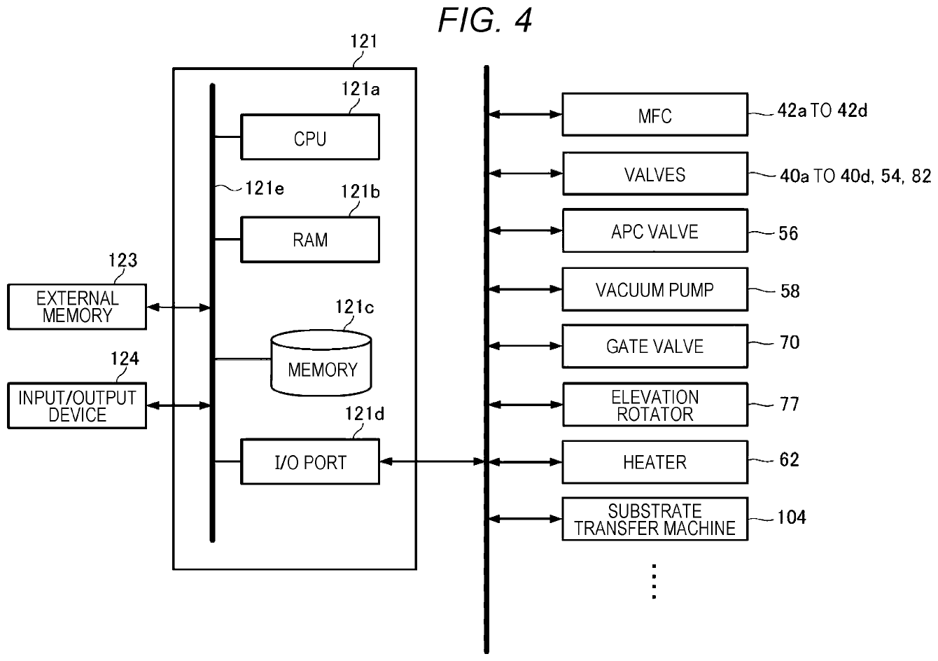

As illustrated in FIG. 4, the controller 121 is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 124 configured as, for example, a touch panel or the like is connected to the controller 121.

The memory 121c includes, for example, a flash memory, a hard disk drive (HDD), or the like. A control program that controls the operation of the substrate processing apparatus, a process recipe in which procedures, conditions, and the like of substrate processing described later are described, and the like are readably stored in the memory 121c. Furthermore, the process recipe is combined so as to function as a program that causes the controller 121 to perform each procedure in the substrate processing process, described later, to obtain a predetermined result. Hereinafter, the process recipe, the control program, and the like are also collectively and simply referred to as a program. Furthermore, when the term “program” is used in the present specification, it may indicate a case of including the process recipe, a case of including the control program, or a case of including both the process recipe and the control program. In addition, the RAM 121b is configured as a memory area (work area) in which the program, data, and the like read by the CPU 121a are temporarily stored.

The I/O port 121d is connected to the MFCs 42a to 42d, the valves 40a to 40d, 54, and 82, the APC valve 56, the vacuum pump 58, the gate valve 70, the elevation rotator 77, the heater 62, which are described above, a substrate transfer machine 104, and the like.

The CPU 121a is configured to read the control program from the memory 121c and perform the control program, and to read the process recipe from the memory 121c in response to an input or the like of an operation command from the input/output device 124. Then, the CPU 121a is configured to control, in accordance with the content of the read process recipe, a heating and cooling operation of the substrate 12 by the heater 62, a pressure regulating operation by the APC valve 56, flow rate regulating operations of the respective gases by the MFCs 42a to 42d and the valves 40a to 40d, 54, and 82, an elevation rotation operation of the susceptor 64 by the elevation rotator 77, and the like.

Furthermore, the controller 121 is not limited to a configuration as a dedicated computer, and may be configured as a general-purpose computer. The controller 121 in the embodiments can be configured by preparing an external memory (for example, a magnetic tape, a magnetic disk such as a flexible disk or a hard disk, an optical disk such as a CD or a DVD, a magneto-optical disk such as an MO, or a semiconductor memory such as a USB memory (USB flash drive) or a memory card) 123 storing the above-described program, for example, and installing the program into a general-purpose computer using the external memory 123. Furthermore, the means for supplying the program to the computer is not limited to the case of supplying the program via the external memory 123. For example, the program may be supplied using a communication means such as the Internet or a dedicated line without via the external memory 123. Furthermore, the memory 121c and the external memory 123 are configured as computer-readable recording media. Hereinafter, the memory 121c and the external memory 123 are also collectively and simply referred to as a recording medium. Furthermore, when the term “recording medium” is used in the present specification, it may indicate a case of including the memory 121c, a case of including the external memory 123, or a case of including both the memory 121c and the external memory 123.

(2) Substrate Processing Process

Next, a process in which a thin film is formed on the substrate 12 by using the process container 202 of the substrate processing apparatus having the above-described configuration will be described as one of the processes of manufacturing a semiconductor. Furthermore, in the following description, the controller 121 controls the operation of each constituent included in the substrate processing apparatus.

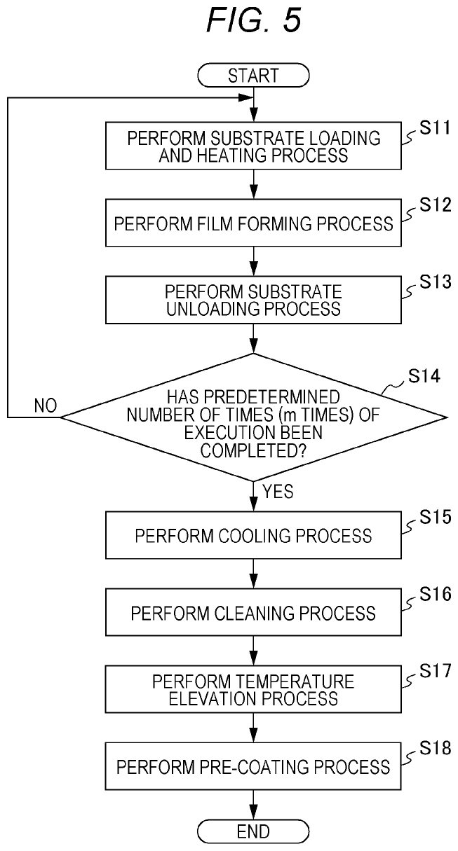

FIG. 5 is a flowchart illustrating an outline of the substrate processing process according to some embodiments of the present disclosure.

(Substrate Loading and Heating Process: S11)

First, the susceptor 64 is lowered to the substrate transfer position B illustrated in FIG. 2 by the elevation rotator 77, and the support pins 74 are made to pass through through-holes 65 of the susceptor 64. As a result, the support pins 74 are brought into a state where the support pins 74 protrude from the surface of the susceptor 64 by a predetermined height. Subsequently, the gate valve 70 is opened to allow the transfer region 22b to communicate with the substrate transfer chamber 103. Then, the substrate 12 is loaded from the substrate transfer chamber 103 to the transfer region 22b using the substrate transfer machine 104, and the substrate 12 is transferred onto the support pins 74. As a result, the substrate 12 is supported in a horizontal posture on the support pins 74 protruding from the surface of the susceptor 64.

After the substrate 12 is loaded into the process chamber 22, the substrate transfer machine 104 is retracted to the outside of the process chamber 22, and the gate valve 70 is closed to seal the process chamber 22. Thereafter, the susceptor 64 is elevated by the elevation rotator 77 to mount the substrate 12 on the mounting surface of the susceptor 64. Then, the susceptor 64 is further elevated to the substrate processing position A to elevate the substrate 12 to the process region 22a.

When the substrate 12 is loaded into the process region 22a, and the susceptor 64 is elevated to the substrate processing position A, the valve 54 is opened to allow the process region 22a and the APC valve 56 to communicate with each other and allow the APC valve 56 and the vacuum pump 58 communicate with each other. The APC valve 56 regulates the conductance of the exhaust pipe 50 to control the exhaust flow rate of the process region 22a by the vacuum pump 58, and maintains the pressure inside the process region 22a at a predetermined pressure.

In this manner, in the substrate loading and heating process (S11), the pressure inside the process chamber 22 is controlled to be a predetermined pressure, and the heater 62 is controlled such that the surface temperature of the substrate 12 becomes a processing temperature, for example, between 700 to 1000° C.

Furthermore, the processing temperature inside the present specification means the temperature of the substrate 12 or the temperature inside the process chamber 22, and the processing pressure means the pressure inside the process chamber 22. In addition, a processing time means the time during which the processing is continued. The same applies to the following description.

In addition, in the present specification, the expression of the numerical range such as “700 to 1000° C.” means that a lower limit value and an upper limit value are included in the range. Therefore, for example, “700 to 1000° C.” means “700° C. or more and 1000° C. or less”. The same applies to other numerical ranges.

(Film Forming Process: S12) Next, as the film forming process (S12), the following steps S101 to S105 are performed. In the film forming process (S12), a process in which different process gases are alternately supplied is repeated.

In addition, in the film forming process, in a state where the substrate 12 is supported on the susceptor 64 at the substrate processing position A illustrated in FIG. 1, the substrate 12 is heated and a process gas is supplied into the process region 22a partitioned by the susceptor 64. Therefore, the film forming process may be referred to as a substrate processing process.

(Supply of Source Gas: Step S101)

First, a source gas is supplied to the substrate 12 in the process region 22a and is exhausted from the process region 22a. Specifically, the valve 40a is opened to cause the source gas to flow into the gas supply pipe 38a. The flow rate of the source gas is regulated by the MFC 42a. The source gas is supplied into the process region 22a through the gas supply pipe 36, the gas introduction port 34, and the gas introducer 26, and is exhausted from the exhaust pipe 50 through the annular passage 66 and the exhaust hole 48. At this time, the valve 40c may be opened to cause an inert gas to be supplied from the gas supply pipe 38c. At this time, the valve 54 is set to an open state, and the APC valve 56 controls the pressure inside the process region 22a to be a predetermined processing pressure.

By supplying the source gas to the substrate 12 in this step, a first layer is formed on the substrate 12.

As the source gas, for example, a source gas containing silicon (Si) can be used. As the source gas containing Si, for example, a chlorosilane-based gas such as a dichlorosilane (SiH₂Cl₂, abbreviation: DCS) gas, a trichlorosilane (SiHCl₃, abbreviation: TCS) gas, a tetrachlorosilane (SiCl₄, abbreviation: STC) gas, or a hexachlorodisilane (Si₂Cl₆, abbreviation: HCDS) gas, a fluorosilane-based gas such as a tetrafluorosilane (SiF₄) gas, an inorganic silane-based gas such as a disilane (Si₂H₆, abbreviation: DS) gas, or an amino silane-based gas such as a trisdimethylaminosilane (Si[N(CH₃)₂]₃H, abbreviation: 3DMAS) gas can be used. One or more of these gases can be used as the source gas.

As the inert gas, for example, a nitrogen (N₂) gas or a rare gas such as an argon (Ar) gas, a helium (He) gas, a neon (Ne) gas, or a xenon (Xe) gas can be used. One or more of these gases can be used as the inert gas.

(Purge: Step S102) After the supply of the source gas is stopped, the process region 22a is purged. Specifically, the valve 40a is closed to stop the supply of the source gas. At this time, the inside of the process region 22a is vacuum-exhausted by the vacuum pump 58 with the APC valve 56 kept open, and the source gas remaining inside the process region 22a and having not reacted or after having contributed to the formation of the first layer and by-products are removed from the inside of the process region 22a. At this time, the supply of the inert gas into the process region 22a is maintained with the valve 40c kept open. The inert gas acts as a purge gas.

(Supply of Reactant Gas: Step S103)

Subsequently, a reactant gas is supplied to the substrate 12 in the process region 22a and is exhausted from the process region 22a. Specifically, the valve 40b is opened to cause the reactant gas to flow into the gas supply pipe 38b. The flow rate of the reactant gas is regulated by the MFC 42b. The reactant gas is supplied into the process region 22a through the gas supply pipe 36, the gas introduction port 34, and the gas introducer 26, and is exhausted from the exhaust pipe 50. At this time, the valve 40c may be opened to cause the inert gas to be supplied from the gas supply pipe 38c. At this time, the valve 54 is set to an open state, and the APC valve 56 controls the pressure inside the process region 22a to be a predetermined processing pressure.

By supplying the reactant gas to the substrate 12 in this step, the first layer formed on the substrate 12 is modified into a second layer.

As the reactant gas, for example, an N-containing gas containing nitrogen (N) can be used. As the N-containing gas, for example, a hydrogen nitride-based gas such as an ammonia (NH₃) gas, a diazene (N₂H₂) gas, a hydrazine (N₂H₄) gas, or an N₃H₈ gas can be used. One or more of these gases can be used as the reactant gas.

(Purge: Step S104)

After the supply of the reactant gas is stopped, the process region 22a is purged. Specifically, the valve 40b is closed to stop the supply of the reactant gas. At this time, the inside of the process region 22a is vacuum-exhausted by the vacuum pump 58 with the APC valve 56 kept open, and the reactant gas remaining inside the process region 22a and having not reacted or after having contributed to the modification to the second layer and by-products are removed from the inside of the process region 22a. At this time, the supply of the inert gas into the process region 22a is maintained with the valve 40c kept open. The inert gas acts as a purge gas.

(Predetermined Number of Times Execution: Step S105)

Steps S101 to S104 described above are defined as one cycle, and the cycle is performed a predetermined number of times (n times, n being an integer of one or more) to form a predetermined film on the substrate 12. For example, a silicon nitride film (SiN film) is formed as the predetermined film.

(Substrate Unloading Process: S13)

After a predetermined film is formed on the substrate 12, the susceptor 64 is lowered to the substrate transfer position B for the substrate 12 by the elevation rotator 77, and the processed substrate 12 is unloaded from the process chamber 22 to the substrate transfer chamber 103, which are in the reverse order of the procedures in the substrate loading and heating process (S11) described above.

(Determination Process: S14)

The substrate loading and heating process (S11), the film forming process (S12), and the substrate unloading process (S13) described above are defined as one cycle, and the controller 121 determines whether the cycle has been performed a predetermined number of times (m times, m being an integer of one or more) (S14). Then, in a case where the cycle has not been performed a predetermined number of times, the processing returns to step S11, and the next waiting unprocessed substrate 12 is loaded into the process chamber 22 in the same procedures as the substrate loading and heating process (S11), and the film forming process (S12) described above is to be performed on the loaded substrate 12. Then, in a case where the cycle has been performed a predetermined number of times, a cooling process (S15), which is the next process, is performed.

(Cooling Process: S15)

In the cooling process (S15), power supply to the heater 62 is stopped, and the gate valve 70 is closed. Then, the susceptor 64 is lowered to the cooling position C illustrated in FIG. 3 by the elevation rotator 77, and a cooling gas is supplied into both the process region 22a and the transfer region 22b for a predetermined time. Here, the cooling position C is located below the substrate processing position A, preferably at the substrate transfer position B, more preferably below the substrate transfer position B. In this manner, the distance between the mounting surface of the susceptor 64 and the gas introducer 26 is increased to expand the volume of the space above the susceptor 64. That is, in a state where the susceptor 64 is moved to the transfer region 22b below the process region 22a, the cooling gas is supplied into the process chamber 22 for a predetermined time, and the temperature inside the process chamber 22 is cooled down to a cleaning temperature, which is a predetermined temperature and lower than the processing temperature, or less.

Here, when steps S11 to S13 described above are performed a predetermined number of times, a film is deposited on an inner wall surface of the process chamber 22, members such as the susceptor 64, and the like. The film deposited in the process chamber 22 may result in particles. Therefore, in some cases, the deposited film is removed by performing cleaning processing. In addition, a corrosive gas is used as the cleaning gas used in the cleaning processing. As a result, in some cases, a defect occurs in a portion when the cleaning processing is performed at a high temperature after film forming processing (also referred to as substrate processing) is performed at a high temperature. Therefore, processing of lowering the temperature inside the process chamber 22 to a desired temperature is performed after the film forming processing and before performing the cleaning processing. However, in some cases, it takes time to lower the temperature inside the process chamber 22 from the processing temperature at which the substrate is processed to the cleaning temperature at which the cleaning processing is performed.

In addition, as a method of forming a thin film on a substrate, there are chemical vapor deposition (CVD) and atomic layer deposition (ALD). In the ALD, gas supply and exhaust are performed in a short cycle to replace the gas inside the process chamber, and a film is formed on the substrate. Therefore, in the ALD, the distance between the substrate 12 and the gas introducer 26 is reduced, as illustrated in FIG. 1, so as to increase the gas replacement efficiency, and the volume of the process region 22a, which is the space above the susceptor 64, is reduced, and the film forming processing is performed.

However, supplying the cooling gas while the susceptor 64 is kept at the substrate processing position A after the film forming processing results in supplying the cooling gas into a confined space. When a large amount of cooling gas is supplied into the process region 22a, which is such a confined space, while maintaining the process region 22a at a constant pressure, a flow velocity of the cooling gas supplied into the process region 22a increases. As a result, in some cases, the film deposited on the inner wall surface of the process region 22a inside the process chamber 22 and the susceptor 64 is peeled off.

In contrast, by lowering the position of the susceptor 64 from the substrate processing position A and disposing the susceptor 64 to the transfer region 22b, the space above the susceptor 64 expands. As a result, the supply amount of the cooling gas can be increased without increasing the flow velocity of the cooling gas, so that the cooling efficiency can be improved while suppressing peeling off of the deposited film.

That is, in the embodiments, in a state where the susceptor 64 is moved to the cooling position C below the substrate processing position A and is located in the transfer region 22b below the process region 22a, the cooling gas is supplied into the process chamber 22. As a result, as compared with the case where the cooling gas is supplied with the susceptor 64 located at the substrate processing position A, a large amount of cooling gas can be supplied into the process chamber 22. Furthermore, the process chamber 22 includes the exhaust hole 48 that communicates with the process region 22a, and the exhaust hole 80 that communicates with the transfer region 22b. Therefore, by opening the valves 54 and 82 provided in the exhaust pipes 50 and 81 respectively communicating with the exhaust holes 48 and 80 and performing exhaust, a large amount of cooling gas supplied into the process chamber 22 can be exhausted through the exhaust holes 48 and 80. As a result, cooling time is shortened and the cooling efficiency is improved.

In addition, as described above, the distance between the substrate mounting surface of the susceptor 64 and the gas introducer 26 is increased than the distance between the substrate mounting surface of the susceptor 64 and the gas introducer 26 in the film forming process (S12) described above. As a result, the influence of the heater 62 incorporated in the susceptor 64 can be reduced, and it is possible to suppress an increase in the temperature of the gas introducer 26 caused due to the heat by the heater 62 or the heat accumulated in the susceptor 64.

Specifically, the valves 54 and 82 are set to an open state, and the valve 40c is opened to cause the cooling gas to flow into the gas supply pipe 38c. The flow rate of the cooling gas is regulated by the MFC 42c. The cooling gas is supplied into the process chamber 22 through the gas supply pipe 36, the gas introduction port 34, and the gas introducer 26, and is exhausted from the exhaust pipes 50 and 81 through the exhaust holes 48 and 80.

At this time, the valve 54 is set to an open state, and the APC valve 56 regulates the pressure inside the process chamber 22 to a pressure higher than the pressure inside the process chamber 22 during the film forming process, which is during the substrate processing. For example, the pressure is regulated to be the atmospheric pressure. As a result, the heat conduction effect in the process chamber 22 is enhanced, so that the cooling effect in the process chamber 22 can be enhanced.

Furthermore, in this step, a description has been made by using the case where both the valves 54 and 82 provided in the exhaust pipes 50 and 81 respectively communicating with the exhaust holes 48 and 80 are opened to perform exhaust. However, the pressure inside the process chamber 22 may be controlled by using at least one of the valves 54 and 82. Even in a case where either one of the valves is used, the APC valve 56 can regulate the pressure inside the process chamber 22 to a pressure higher than the pressure inside the process chamber 22 during the substrate processing. As a result, the same effect described above can be obtained.

As the cooling gas, a gas having excellent heat conductivity, for example, an N₂ gas, a helium (He) gas, a hydrogen (H₂) gas, an argon (Ar) gas, or the like can be used. One or more of these gases can be used as the cooling gas.

(Cleaning Process: S16)

In the cleaning process (S16), the cleaning gas is supplied into the process chamber 22 for a predetermined time. At this time, the position of the susceptor 64 may be at any of the substrate processing position A, the substrate transfer position B, or the cooling position C. Then, the cleaning gas is supplied into the process chamber 22 at the cleaning temperature lower than the processing temperature during the substrate processing.

Specifically, the valves 54 and 82 are set to an open state, and the valve 40d is opened to cause the cleaning gas to flow into the gas supply pipe 38d. The flow rate of the cleaning gas is regulated by the MFC 42d. The cleaning gas is supplied into the process chamber 22 through the gas supply pipe 36, the gas introduction port 34, and the gas introducer 26, and is exhausted from the exhaust pipes 50 and 81 through the exhaust holes 48 and 80. At this time, the APC valve 56 controls the pressure inside the process chamber 22 to be a predetermined pressure. As a result, deposits deposited on the gas supply pipe 36, the gas introduction port 34, the gas distributor 30, the inside of the shower plate 32, the susceptor 64, the support shaft 76, the inner wall of the process chamber 22, and the like are removed from the process chamber 22 through the exhaust pipes 81 and 50 by the vacuum pump 58.

That is, in the cleaning process after the cooling process, the cleaning gas is supplied into the process chamber 22 in a state where the substrate 12 is not mounted on the susceptor 64, and the gas supply pipe 36, the gas introduction port 34, the gas distributor 30, the inside of the shower plate 32, the susceptor 64, the support shaft 76, the inner wall of the process chamber 22, and the like are cleaned.

As the cleaning gas, for example, a gas containing a halogen element and containing at least one selected from the group consisting of tetrachlorosilane (SiCl₄), hydrogen chloride (HCl), boron trichloride (BCl₃), chlorine (Cl₂), fluorine (F₂), hydrogen fluoride (HF), silicon tetrafluoride (SiF₄), nitrogen trifluoride (NF₃), chlorine trifluoride (ClF₃), boron tribromide (BBr₃), silicon tetrabromide (SiBr₄), and bromine (Br₂) can be used.

(Temperature Elevation Process: S17)

After the cleaning process (S16), the susceptor 64 is elevated by the elevation rotator 77, and is moved to the substrate processing position A in the process region 22a. Then, the process chamber 22 is heated up to the processing temperature during the substrate processing.

(Pre-coating Process: S18)

When the temperature inside the process chamber 22 is elevated to the processing temperature, the film forming process S12 described above is performed. That is, the source gas and the reactant gas are supplied into the process region 22a in a state where the substrate 12 is not mounted on the susceptor 64 to form a coating film on the inner wall of the process region 22a, the mounting surface of the susceptor 64, and the like. As a result, it is possible to suppress impurities of a halogen element such as fluorine (F), chlorine (Cl), or boron (Br) contained in the cleaning gas from adhering to the substrate 12 as particles.

### Other Embodiments of the Present Disclosure

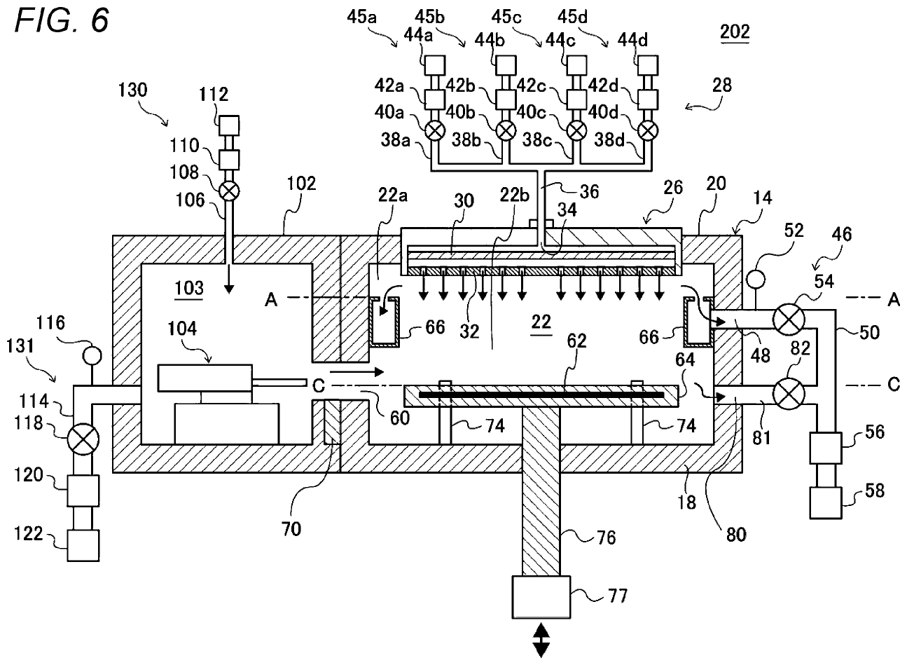

Next, a substrate processing apparatus according to other embodiments of the present disclosure will be described with reference to FIG. 6. Furthermore, in the substrate processing apparatus in the embodiments, constituent elements that are substantially the same as those described in FIG. 1 are denoted by the same reference numerals, and repetitive descriptions may be omitted.

In the embodiments, the cooling process S15 described above is performed by making use of the substrate transfer chamber 103 that communicates with the process chamber 22. The substrate transfer chamber 103 includes a housing 102 disposed adjacent to the container 14. The substrate transfer machine 104 is disposed in the substrate transfer chamber 103.

A gas supply pipe 106 that supplies an inert gas serving as a cooling gas into the substrate transfer chamber 103 is connected to the housing 102. The gas supply pipe 106 is provided with a gas supply source 112, an MFC 110, and a valve 108 in this order from the gas supply upstream direction side. An inert gas supply system 130 includes the gas supply pipe 106, the MFC 110, and the valve 108. The gas supply source 112 may be included in the inert gas supply system 130. The inert gas supply system 130 may be referred to as a cooling gas supply system.

In addition, an exhaust pipe 114 that exhausts the atmosphere inside the substrate transfer chamber 103 is connected to the housing 102. The exhaust pipe 114 is provided with a pressure sensor 116, a valve 118, an APC valve 120, and a vacuum pump 122 in this order from the gas flow upstream direction side. An exhaust system 131 includes the exhaust pipe 114, the pressure sensor 116, the valve 118, and the APC valve 120. The vacuum pump 122 may be included in the exhaust system 131.

Then, the gate valve 70 is opened at the time of supplying the cooling gas from the gas supply pipe 38c in the cooling process S15 in the substrate processing process described above, and the inert gas serving as a cooling gas is supplied from the gas supply pipe 106 to the substrate transfer chamber 103. That is, the controller 121 controls the supply of the cooling gas into the process chamber 22 such that the cooling gas is supplied not only from the gas introducer 26 but also from the substrate transfer chamber 103 that communicates with the process chamber 22. That is, in the cooling process described above, the cooling gas is supplied into both the process region 22a and the transfer region 22b.

That is, in the cooling process (S15) described above, power supply to the heater 62 is stopped, the susceptor 64 is lowered to the cooling position C for the substrate 12 by the elevation rotator 77, and at the cooling position C, the cooling gas is supplied for a predetermined time. That is, in a state where the susceptor 64 is moved to the transfer region 22b below the process region 22a, processing is performed in which the cooling gas is supplied into the process chamber 22 from the gas introducer 26 and the transfer port 60 of the substrate transfer chamber 103 that communicates with the process chamber 22. That is, the cooling gas is supplied into the process chamber 22 for a predetermined time in a state where the substrate 12 is not mounted on the susceptor 64 and the distance between the susceptor 64 and the gas introducer 26 is increased. Furthermore, the process chamber 22 includes the exhaust hole 48 that communicates with the process region 22a, and the exhaust hole 80 that communicates with the transfer region 22b. Therefore, by opening the valves 54 and 82 provided in the exhaust pipes 50 and 81 respectively communicating with the exhaust holes 48 and 80 and performing exhaust, a large amount of cooling gas supplied into the process chamber 22 can be exhausted through the exhaust holes 48 and 80. As a result, cooling time is shortened and the cooling efficiency is improved.

In the embodiments, the same effects as those in some embodiments described above can be obtained. In addition, in the embodiments, the cooling gas is supplied not only from the gas supply system 28 but also from the substrate transfer chamber 103 side that includes no heating mechanism. As a result, the cooling efficiency can be further improved.

Some embodiments of the present disclosure have been described in detail heretofore, but the present disclosure is not limited to the above-described embodiments, and various modifications can be made without departing from the gist of the present disclosure.

For example, in some embodiments described above, a case has been described as an example in which, in the film forming processing performed by the substrate processing apparatus, a Si-containing gas is used as the source gas and an N-containing gas is used as the reactant gas, and the Si-containing gas and the N-containing gas are alternately supplied to form a SiN film on the substrate 12. However, the present disclosure is not limited thereto. That is, the process gas used for the film forming processing is not limited to the Si-containing gas, the N-containing gas, and the like, and another type of gas may be used to form another type of thin film. Furthermore, even in a case where three or more types of process gases are used, the present disclosure can be applied as long as the film forming processing is performed by alternately supplying the three or more types of process gases.

In addition, in some embodiments described above, a case has been described as an example in which a gas similar to the inert gas is used as the cooling gas, but the present disclosure is not limited thereto. That is, a cooling gas supply system may be provided separately from the inert gas supply system.

In addition, in some embodiments described above, a description has been made by using the case in which the cooling process is performed while power supply to the heater 62 is stopped, but the present disclosure is not limited thereto. That is, the cooling process may be performed in a state where power supply to the heater 62 is maintained.

The embodiments described above can be used in combination as appropriate. Processing procedures and processing conditions at this time can be similar to the processing procedures and the processing conditions in the embodiments described above, for example.

According to the present disclosure, the process chamber can be efficiently cooled.

What is claimed is:

1. A substrate processing apparatus comprising:
a substrate mounting table configured to be vertically movable and in which a heating mechanism is incorporated;
a process chamber divided, by movement of the substrate mounting table, into a process region where a substrate is processed and a transfer region that is disposed below the process region and where transfer of the substrate is performed;
a cooling gas supply system configured to supply a cooling gas into the process chamber;
a cleaning gas supply system configured to supply a cleaning gas into the process chamber;
an exhaust system configured to exhaust the process chamber; and
a controller configured to be capable of controlling the substrate mounting table, the cooling gas supply system, the cleaning gas supply system, and the exhaust system so as to perform: supplying the cooling gas into the process chamber in a state where the substrate mounting table is moved below the process region; and supplying the cleaning gas into the process chamber at a temperature lower than a temperature during substrate processing in which the substrate is processed.

2. The substrate processing apparatus according to claim 1, wherein the controller is configured to control a pressure inside the process chamber during the supplying of the cooling gas to a pressure higher than the pressure inside the process chamber during the substrate processing.

3. The substrate processing apparatus according to claim 2, wherein the controller is configured to control the pressure inside the process chamber during the supplying of the cooling gas to be atmospheric pressure.

4. The substrate processing apparatus according to claim 1, wherein the controller is configured to control, during the supplying of the cooling gas, the pressure inside the process chamber by using at least one of an exhaust hole that communicates with the process region and an exhaust hole that communicates with the transfer region.

5. The substrate processing apparatus according to claim 1, wherein the controller is configured to control the supplying of the cooling gas such that the cooling gas is supplied into both the process region and the transfer region.

6. The substrate processing apparatus according to claim 5, wherein the controller is configured to control the supplying of the cooling gas into the transfer region such that the cooling gas is supplied from a substrate transfer chamber that communicates with the process chamber.

7. The substrate processing apparatus according to claim 1, further comprising
a process gas supply system configured to supply a process gas into the process chamber, wherein
the controller is configured to be capable of controlling the process gas supply system and the heating mechanism, after the supplying of the cleaning gas into the process chamber, so as to perform: heating a temperature of the process chamber up to a processing temperature at which the substrate is processed in a state where the substrate mounting table is moved to the process region; and supplying the process gas into the process chamber to form a coating film on an inner wall of the process region.

8. A method of cleaning, comprising:
in a process chamber divided, by vertical movement of a substrate mounting table in which a heating mechanism is incorporated, into a process region where a substrate is processed and a transfer region that is disposed below the process region and where transfer of the substrate is performed,
supplying a cooling gas into the process chamber in a state where the substrate mounting table is moved below the process region; and
supplying a cleaning gas into the process chamber at a temperature lower than a temperature during substrate processing in which the substrate is processed.

9. The method according to claim 8, further comprising:
after the supplying of the cleaning gas,
heating a temperature of the process chamber up to a processing temperature at which the substrate is processed in a state where the substrate mounting table is moved to the process region; and
supplying a process gas into the process chamber to form a coating film on an inner wall of the process region.

10. The method of cleaning according to claim 8, further comprising processing the substrate in the process chamber.

11. A non-transitory computer-readable recording medium storing a program that causes, by a computer, a substrate processing apparatus to perform a process comprising:
in a process chamber divided, by vertical movement of a substrate mounting table in which a heating mechanism is incorporated, into a process region where a substrate is processed and a transfer region that is disposed below the process region and where transfer of the substrate is performed,
supplying a cooling gas into the process chamber in a state where the substrate mounting table is moved below the process region; and
supplying a cleaning gas into the process chamber at a temperature lower than a temperature during substrate processing in which the substrate is processed.

12. The non-transitory computer-readable recording medium storing a program according to claim 11, wherein a pressure inside the process chamber during the supplying of the cooling gas is controlled to a pressure higher than the pressure inside the process chamber during the substrate processing.

13. The non-transitory computer-readable recording medium storing a program according to claim 11, wherein during the supplying of the cooling gas, a pressure inside the process chamber is controlled by using at least one of an exhaust hole that communicates with the process region and an exhaust hole that communicates with the transfer region.

14. The non-transitory computer-readable recording medium storing a program according to claim 11, wherein during the supplying of the cooling gas, the cooling gas is supplied into both the process region and the transfer region.

15. The non-transitory computer-readable recording medium storing a program according to claim 14, wherein during the supplying of the cooling gas into the transfer region, the cooling gas is supplied from a substrate transfer chamber that communicates with the process chamber.

16. The non-transitory computer-readable recording medium storing a program according to claim 11, further comprising:
after the supplying of the cleaning gas,
heating a temperature of the process chamber up to a processing temperature at which the substrate is processed in a state where the substrate mounting table is moved to the process region; and
supplying a process gas into the process chamber to form a coating film on an inner wall of the process region.
